(19) United States
(12) Patent Application Publication
(10) Pub. No.: US 2005/0066878 A1
(43) Pub. Date: Mar. 31, 2005

(54) Methods for producing group III nitride materials

(76) Inventors: Douglas Jay Arent, Conifer, CO (US); Calvin J. Curtis, Lakewood, CO (US); Carl Richard Schwerdtfeger JR., Chagrin Falls, OH (US)

Correspondence Address: FAEGRE & BENSON LLP;PATENT DOCKETING, 2200 WELLS FARGO CENTER, 90 SOUTH 7TH STREET, MINNEAPOLIS, MN, 55402-3901, US

(21) Appl. No.: 10/671,840

(22) Filed: Sep. 25, 2003

(51) Int. Cl. C30B 1/00

(52) U.S. Cl. 117/2

(57) ABSTRACT

The present invention provides a method for producing Group III nitride materials by converting a Group III azide of the formula:
(R¹R²N)₂M¹N₃ under conditions sufficient to produce a Group III nitride material of the formula:
M¹N wherein
each of R¹ and R² is independently a hydrocarbyl; and
M¹ is a Group III metal.

### STATEMENT REGARDING FEDERALLY FUNDED RESEARCH

This invention was made with Government support under Contract No. DE-AC36-99GO10337 awarded by the Department of Energy. The Government has certain rights in this invention.

### FIELD OF THE INVENTION

The present invention relates to a method for producing Group III metal nitride materials.

### BACKGROUND OF THE INVENTION

Group III nitride materials, such as GaN, AlN, InN and mixtures thereof, are useful semiconductor materials. For example, GaN material has a large bandgap of blue to ultraviolet wavelength energy. Therefore, there is a wide interest in developing optical semiconductor devices having GaN active layer. These devices are particularly useful in optical information storage devices including a digital video data recorder (DVD). See, for example, U.S. Pat. No. 6,592,663, which is incorporated herein by reference in its entirety.

Conventionally, there are a variety of methods for producing bulk crystal Group III nitride materials, such as GaN. For example, Porowski (J. Crystal Growth, 1998, 189/190, 153-158, discusses synthesis of GaN bulk crystal from a Ga melt under an elevated temperature of 1400-1700° C. and an elevated N₂ pressure of 12-20 kbar. Further the process of Porowski requires a specially built pressure-resistant apparatus and a long time is needed for loading or unloading a source material, or increasing or decreasing the pressure and temperature. Thus, this process is not readily amenable for mass-production of GaN bulk crystals.

Another method for producing bulk crystal GaN is disclosed by Yamane et al., in Chem. Mater., 1997, 9, 413-416. Unlike the Porowski process, Yamane et al. avoid using the extremely high-pressure by conducting the growth of the GaN bulk crystal from a gallium (Ga) melt in the presence of a sodium (Na) flux. Specifically, the process of Yamane et al. combines a metallic Ga source and a sodium azide flux in a pressure-resistance reaction vessel of stainless steel under a nitrogen atmosphere. The reaction mixture is then heated to a temperature of 600-800° C. for a period of from 24 to 100 hours. It is believed that heating increases the pressure inside the reaction vessel to the order of 100 kg/cm² (about 10 MPa), which is substantially lower than the pressure used by Porowski. The solid GaN crystals are then precipitated from the melt of a Na-Ga system.

Without being bound by any theory, it is believed that the process of Yamane et al. relies upon the initially confined N₂ molecules in the atmosphere and the N atoms contained in the NaN₃ flux for the source of N. Thus, when the reaction proceeds, the N₂ molecules in the atmosphere or the N atoms in the Na-Ga melt are depleted with the precipitation of the GaN crystal, and there appears a limitation in growing a large bulk crystal of GaN. The GaN crystals obtained by the process of Yamane et al. typically have a size of 1 mm or less in diameter. Thus, the process of Yamane et al., while being successful in forming GaN bulk crystals at a relatively low pressure and temperature, it too is not amenable for a mass production of GaN substrates in an industrial scale.

Therefore, there remains a need for a method for producing Group III nitride materials, preferably one that does not require a high temperature and/or a high pressure.

### SUMMARY OF THE INVENTION

One aspect of the present invention provides a method for producing a Group III nitride material. In one embodiment, methods of present invention comprise a fluid medium based crystal growth of the Group III Nitride material.

In one particular embodiment, the method for producing the Group III nitride material comprises converting a Group III azide of the formula:
(R¹R²N)₂M¹N₃
to a Group III nitride material of the formula:
M¹N
where each of R¹ and R² is independently a hydrocarbyl; and M¹ is a Group III metal. It is believed that the conversion from the Group III azide to the Group III nitride comprises decomposition of the azide moiety. Such decomposition can be achieved by a variety of methods including, but not limited to, thermolysis and photolysis.

### DETAILED DESCRIPTION OF THE INVENTION

Definitions

“Alkyl” refers to a saturated linear monovalent hydrocarbon moiety of one to twelve, preferably one to six, carbon atoms or a saturated branched monovalent hydrocarbon moiety of three to twelve, preferably three to six, carbon atoms. Exemplary alkyl groups include, but are not limited to, methyl, ethyl, n-propyl, 2-propyl, tert-butyl, pentyl, and the like.

“Fluid” refers to a gas, a liquid or a combination thereof. A preferred fluid is a liquid.

The terms “Group III metal” and “Group III” are used interchangeably herein and refer to elements which are listed in the Group III of the periodic table. Exemplary Group III metals include B, Al, Ga, In and Tl.

The terms “halo,” “halogen” and “halide” are used interchangeably herein and refer to fluoro, chloro, bromo, or iodo.

“Hydrocarbyl” refers to a compound having at least one carbon atom. Such compounds include aryl, alkyl, alkenyl, alkynyl and a combination of two or more thereof. Moreover, hydrocarbyl can be a straight chain, a branched chain, or a cyclic system. Hydrocarbyl can also be substituted with other non hydrogen or carbon atoms such as halide, oxygen, sulfur, or nitrogen. Preferred hydrocarbyls are moieties containing only carbon atom back-bone which is substituted with hydrogen atoms, halide(s) or a combination thereof.

“Lattice Constant” generally refers to a length that denotes the size of the unit cell in a crystal lattice. With respect to the cubic crystal, this is the length of the side of the unit cell. However, a simple definition of the term is difficult, and the term “lattice constant” must be considered with the geometry of the crystal structure in each case. In some instances, depending on the symmetry of the crystal lattice structure, there could be as many as (3) lattice constants, one along each of the length, width, and height of the unit cell for the crystal lattice of interest.

As used herein, the term “treating”, “contacting” or “reacting” refers to adding or mixing two or more reactants under appropriate conditions to produce the indicated and/or the desired product. It should be appreciated that the reaction which produces the indicated and/or the desired product may not necessarily result directly from the combination of reactants that were initially added, i.e., there may be one or more intermediates which are produced in the mixture which ultimately leads to the formation of the indicated and/or the desired product.

As used herein, the terms “those defined above” and “those defined herein” when referring to a variable incorporates by reference the broad definition of the variable as well as preferred, more preferred and most preferred definitions, if any.

General Overview

Group III nitride materials include, but are not limited to, GaN, AlN, InN, GaₓAl_{y}In_{z}N (where the subscripts x, y and z represent a relative ratio of each metal and the sum of subscripts x+y+z=1) and nitride materials containing other Group III metal(s). These materials are useful in a wide variety of electronic devices, especially as semiconductor materials. The present invention provides a fluid medium based method for preparing nano crystals and/or bulk crystals of Group III nitride materials.

Synthesis of Group III Nitride Materials

In one particular aspect, the present invention provides a method for producing a Group III nitride material by converting a Group III azide of the formula:
(R¹R²N)₂M¹N₃
to a Group III nitride material of the formula:
M¹N
where each of R¹ and R² is independently a hydrocarbyl; and M¹ is a Group III metal.

Conversion of the Group III azide to the corresponding Group III nitride material can be accomplished in a variety of manner. In one embodiment, the conversion comprises decomposition of the Group III azide under appropriate conditions, such as thermal decomposition at an elevated temperature as described in detail below. In another embodiment, the conversion can comprise photolysis or photo decomposition, for example, by irradiation with light of appropriate energy level such as UV light. Other suitable conversion methods include the use of plasma, or catalyst (such as platinum or palladium), a reagent (such as hydrogen) and can include materials which provide dopants such as Beryllium, Manganese, Silicon, Zinc, and Germanium.

The ligands R¹ and R² can be selected independently to modify the properties of the Group III azide, including decomposition temperature and stability. Typically, however, R¹ and R² are independently a lower alkyl (i.e., C₁-C₈ alkyl). A particularly preferred R¹ and R² are independently selected from methyl, ethyl, propyl, 2-propyl, n-butyl, sec-butyl, t-butyl, neopentyl, and phenyl. An especially preferred R¹ and R² are independently selected from methyl and ethyl.

Preferably, M¹ is Ga, In, Al or a mixture thereof, i.e., an alloy of the formula GaₓAl_{y}In_{z}, where the subscripts x, y and z are the relative ratio of each metal with the sum of x+y+z being 1. In one particular embodiment of the present invention, M¹ is gallium.

Unlike some conventional processes, the present invention does not require a vapor deposition process or an extreme temperature or pressure. Typically, the method of the present invention is conducted in a fluid medium, preferably in a solution. Given the disclosure provided herein, one skilled in the art will readily recognize that a wide variety of solvents can be used in the present invention. The choice of solvent is often based in part on its ability to withstand temperatures above the decomposition temperature of the Group III azide. Typically, however, any solvent that is inert to the reaction conditions or solvents that can act as the reagent that can convert the Group III azide into the Group III nitride material can be used as the reaction solvent. Exemplary solvents which are useful in the method of present invention include diethyleneglycol dimethyl ether (diglyme), triethyleneglycol dimethyl ether (triglyme), tetraethyleneglycol dimethyl ether (tetraglyme), trioctyl amine (TOA), and trioctyl phosphine (TOP). Typically, triglyme or TOA is used as a reaction solvent.

The reaction is usually conducted under an atmosphere, such as nitrogen, argon, a nitrogen-atom containing (e.g., an amine compound such as ammonia), hydrogen, helium or a combination thereof In one particular embodiment, the reaction atmosphere is a nitrogen-atom containing compound, e.g., an amine compound of the formula:
NR³R⁴R⁵
where each of R³, R⁴ and R⁵ is independently hydrogen or hydrocarbyl.

Preferably, each of R³, R⁴ and R⁵ is independently hydrogen or alkyl. In addition, a mixture of amine compounds can also be used, for example, where one amine compound is ammonia and the other amine compound can be a mono-, di- or a trialkyl amine compound. In one specific embodiment, the reaction atmosphere used to convert the Group III azide to the Group III nitride material is ammonia.

While any suitable reaction vessels known to one skilled in the art can be used for the synthesis of Group III nitride materials, nitrogen-containing crucibles are often used. In particular, a boron nitride crucible and a silicon nitride crucible are typically used as a reaction vessel.

A variety of factors influence the reaction rate and/or the yield of the Group III nitride material, including the reaction solvent, the reagent, reactivity of the Group III azide, the concentration of each reactants, and the reaction temperature and pressure, etc.

The reaction is generally conducted at a temperature ranging from about 100° C. to about 700°C. which depends on a variety of factors such as those enumerated above. Generally, the reaction between the Group III azide and the reagent is conducted at temperature in the range of about 100° C. to about 400° C., with the reaction temperature in the range of from about 200° C. to about 300° C. being particularly preferred.

The reaction time can range from a few hours to a few days depending on a variety of factors, including those factors enumerated above. In general, however, the reaction time ranges from about 2 hour to about 96 hours. Typically, the reaction time ranges from about 8 hours to about 48 hours, and more typically from about 12 hours to about 24 hours.

The reaction pressure depends on a variety of factors, such as those discussed above, including the reaction temperature, solvent, and the reactivity of the reactants. Broadly speaking, the reaction pressure can range from about 1 atm to about 1000 atm with from about 1 atm to about 10 atm being a typical reaction pressure range.

The Group III nitride material can be separated (i.e., isolated) from the reaction mixture using any of the separation techniques known to one skilled in the art, including crystallization, filtration, and chromatographic separations, etc. Because of its ease of isolation, in most cases the Group III nitride material is obtained via a crystallization process. The Group III nitride material can be crystallized from a supersaturated solution. While the reaction mixture can be subjected to standard reaction work-up conditions prior to being subjected to a crystallization process, the present inventors have found that supersaturation and crystallization of the Group III nitride material can be achieved simply by cooling the reaction mixture without any work-up. This crystallization step without any work-up significantly reduces the time and cost associated with isolating the Group III nitride material from the reaction mixture.

Group III nitride can crystallize continuously from the mixture after an induction period in which the solution becomes saturated due to precursor, i.e., Group III azide, decomposition (i.e., MN formation). Crystallization can also be controlled by adding the precursor continuously to the reaction mixture thereby allowing the crystals to grow continuously.

Typically, supersatuation of the Group III nitride material is achieved by cooling the reaction mixture at a rate of from about 0.001° C./hr to about 1° C./hr. As one skilled in the art will readily recognize, in some instances the rate of cooling may affect the purity and/or the yield of the Group III nitride material. In general, a lower cooling rate results in a higher product purity. Accordingly, the reaction mixture is typically cooled at a rate of about 0.005° C./hr to about 0.5° C./hr. More often the cooling rate of the reaction mixture ranges from about 0.01° C./hr to about 0.2° C./hr.

The crystallization process can also include adding a nucleation site or seed, i.e., a solid with a similar lattice constant to the desired Group III nitride material. It should be appreciated that the lattice constant of Group III nitride material is different for different Group III metals or Group III metal alloys. Preferably, the nucleation seed has a lattice constant within ±20% of the desired Group III nitride material. A particularly preferred nucleation seed has a lattice constant within ±10% of the desired Group III nitride material.

The nucleation seed can be added to the crystallization process in a variety of manners. For example, the nucleation seed can be added to the crystallization mixture simply by adding the nucleation seed into the reaction mixture (i.e., “top-seeded solution growth”) or using an apparatus known as a seed holder. The seed holder can be an integral part of the reaction vessel and can be used for “bottom-seeded solution growth” or “side-seeded solution growth.” For example, the reaction vessel can have a protrusion or a “nipple”, on the bottom or side of the reaction vessel. The nucleation seed can be attached to, or placed in that protrusion. As the reaction mixture is cooled, the protrusion is one of the first areas of the reaction vessel to cool, thus nucleating the Group III Nitride on the seed crystal. Without being bound by any theory, it is believed that by nucleating on the side of the reaction vessel (similar to a horizontal Bridgman system) rather than the top or bottom, some advantages in terms of convective solvent transport can be achieved.

Synthesis of Group III Azides

The Group III azide of the formula (R¹R²N)₂M¹N₃, where R¹, R² and M¹ are those defined herein, can be prepared using any of the methods known to one skilled in the art. In one particular embodiment, the Group III azide is prepared from a Group III metal amide of the formula:
(R¹R²N)₂M¹X¹
by reacting the Group III metal amide with a metal azide under conditions sufficient to produce the Group III azide, where X¹ is a ligand, such as halide, carboxylate (e.g., acetate, formate, etc.), sulfonate, and other metal ligands known to one skilled in the art.

Preferably, the ligand X¹ is halide. A particularly preferred X¹ is chloride, iodide or bromide. An especially preferred X¹ is chloride.

Suitable metal azides for the synthesis of Group III azide are those in which the azide moiety is sufficiently nucleophilic to displace the ligand X¹ under the reaction conditions. Exemplary metal azides that are useful in methods of present invention include, but are not limited to, Group I metal azides, such as NaN₃, LiN₃, KN₃, and CsN₃; Group II metal azides, such as Mg(N₃)₂, Ca(N₃)₂, and Ba(N₃)₂; and transition metal azides. While the present invention is described in reference to using a metal azide, it should be appreciated that other azide sources, such as tetraalkylammonium azide and the like, can also be used.

Reaction conditions for preparing the Group III azide can vary depending on a variety of factors, including those factors discussed for the synthesis of the Group III nitride materials above. Typically, synthesis of the Group III azide is conducted in an inert solvent such as methylene chloride, chloroform, ether, toluene, tetrahydrofuran (THF), dimethylsulfoxide (DMSO), and N,N-dimethylformide (DMF), etc. A mixed solvent system can also be used.

The reaction temperature can range anywhere from 0° C. to the boiling point of the reaction solvent. Typically, the reaction temperature ranges from 0° C. to about 50° C. Often, however, the reaction temperature is near the ambient temperature (i.e., 20-25° C.) to slightly above the ambient temperature (e.g., 30-40° C.).

Synthesis of Group III Metal Amides

The Group III metal amide of the formula (R¹R²N)₂M¹X¹, where X¹, R¹, R² and M¹ are those defined herein, can be prepared using any of the methods known to one skilled in the art. In one particular embodiment, the Group III metal amide is prepared by reacting a Group III metal salt of the formula M¹(X¹)₃, with a metal amide compound of the formula M²NR¹R², where M¹, M², R¹, R₂ and X¹ are those defined herein.

Some metal amines are commercially available. Other metal amides can be readily obtained by one skilled in the art, for example, by reacting a corresponding amine (i.e., HNR¹R²) with a metal M² or an organometallic compound of the formula M²R⁶, where R⁶ is an alkyl or aryl, typically methyl, butyl, t-butyl, sec-butyl, or phenyl. In one particular embodiment, M² is Li, K, Na, or Mg(X²)₂ (wherein X² is halide).

Reaction conditions for preparing the Group III metal amide are well known to one skilled in the art. Typically, the Group III metal amide is synthesized in an inert reaction solvent such as ether, toluene or tetrahydrofuran (THF) etc.

The reaction temperature generally ranges from about −78° C. to about 0° C. A typical reaction temperature is about −78° C.

It should be appreciated that reaction conditions employed in methods of the present invention are not limited to those specific ranges and examples given herein. Still further, combinations of the preferred groups and/or methods described herein form other preferred embodiments. For example, in one particularly preferred embodiment, synthesis of the Group III nitride material begins with a Group III metal salt. In this manner, a variety of preferred methods are embodied within the present invention.

### EXAMPLES

The following examples are offered to illustrate, but not to limit the claimed invention.

### Example 1

A GaN seed crystal is placed in a boron nitride crucible along with triglyme and the mixture is purged with nitrogen to remove air. An air-free solution of bis(dimethylamido)gallium azide in triglyme is then added to the crucible by syringe. The reaction mixture was then heated to 260° C. for 4 hours. The reaction mixture is then allowed to cool at a rate of 1° C./hr to a temperature of 25° C. to afford crystalline GaN.

It is understood that the examples and embodiments described herein are for illustrative purposes only and that various modifications or changes in light thereof will be suggested to persons skilled in the art and are to be included within the spirit and purview of this application and scope of the appended claims. All publications, patents and patent applications cited herein are hereby incorporated by reference in their entirety for all purposes.

1. A method for producing a Group III nitride material, said method comprising converting a Group III azide of the formula:
(R¹R²N)₂M¹N₃
under conditions sufficient to produce a Group III nitride material of the formula:
M¹N
wherein
each of R¹ and R² is independently a hydrocarbyl; and
M¹ is a Group III metal.

2. The method of claim 1, wherein the Group III azide is produced by the step comprising:
(a) reacting a Group III metal salt of the formula:
M¹(X¹)₃
with a metal amide compound of the formula:
M²NR¹R²
under conditions sufficient to produce a Group III metal amide of the formula:
(R¹R²N)₂M¹X¹
and
(b) reacting the Group III metal amide with a metal azide to produce the Group III azide,
wherein
M² is a Group I or Group II metal ion;
each X¹ is independently a ligand; and
M¹, R¹ and R² are those defined in claim 1.

3. The method of claim 2, wherein each X¹ is independently a halide.

4. The method of claim 2, wherein the metal azide is selected from the group consisting of sodium azide, lithium azide, potassium azide, cesium azide, ammonium azide, and a combination thereof.

5. The method of claim 1, wherein the reaction atmosphere comprises an amine compound, an inert gas or a combination thereof.

6. The method of claim 5, wherein the amine compound is of the formula:
NR³R⁴R⁵
wherein each of R³, R⁴ and R⁵ is independently hydrogen or hydrocarbyl.

7. The method of claim 6, wherein the reaction atmosphere comprises the amine compound, nitrogen, argon, helium or a mixture thereof.

8. The method of claim 7, wherein the amine compound comprises ammonia.

9. The method of claim 1, wherein M¹ is selected from the group consisting of Ga, Al, In, and a mixture thereof.

10. The method of claim 1, wherein the reaction temperature is from about 100° C. to about 700° C.

11. The method of claim 1, wherein the reaction temperature is from about 100° C. to about 400° C.

12. The method of claim 1, wherein the reaction temperature is from about 200° C. to about 300° C.

13. The method of claim 10 further comprising crystallizing the Group III nitride material from the reaction mixture by cooling the reaction temperature until a super saturated solution is achieved.

14. The method of claim 13, wherein the reaction cooling rate is in the range of about 0.001° C./hr to about 1° C./hr.

15. The method of claim 13 further comprising introducing a nucleation site to the reaction mixture.

16. The method of claim 15, wherein the nucleation site comprises a seed crystal of material with a similar lattice constant relative to the Group III nitride material.

17. The method of claim 1, wherein the reaction pressure is from about 1 atmosphere to about 1000 atmospheres.

18. The method of claim 1, wherein a reaction vessel comprises a nitrogen-containing crucible.

19. The method of claim 18, wherein the nitrogen-containing crucible comprises a boron nitride crucible or a silicon nitride crucible.

20. The method of claim 1, wherein the Group III nitride material is in a nano crystal form.

21. The method of claim 1, wherein the Group III nitride material is in a bulk crystal form.

22. The method of claim 1, wherein said step of converting the Group III azide to the Group III nitride comprises decomposition of the Group III azide to the Group III nitride.

23. The method of claim 22, wherein said decomposition comprises thermal decomposition.

24. The method of claim 22, wherein said decomposition comprises photodecomposition.

25. A method for producing a Group III nitride material, said method comprising:
(a) reacting a Group III metal salt of the formula:
M¹(X¹)₃
with a metal amide compound of the formula:
M²NR¹R²
under conditions sufficient to produce a Group III metal amide of the formula:
(R¹R²N)₂M¹X¹
(b) reacting the Group III metal amide with a metal azide under conditions sufficient to produce a Group III azide of the formula:
(R¹R²N)₂M¹N₃
and
(c) decomposing the Group III azide under conditions sufficient to produce a Group III nitride material of the formula:
M¹N
wherein
M¹ is a Group III metal;
M² is a Group I or Group II metal ion;
each X¹ is independently a ligand; and
each of R¹ and R² is independently a hydrocarbyl.

26. The method of claim 25, wherein M¹ is selected from the group consisting of Ga, Al, In, and a mixture of two or more thereof.

27. The method of claim 25, wherein said decomposition step comprises thermal decomposition.

28. The method of claim 27, wherein said thermal decomposition comprises heating the Group III azide to a temperature of at least 100° C.

29. The method of claim 28, wherein said thermal decomposition comprises heating the Group III azide to a temperature range of from about 200° C. to about 300° C.

30. The method of claim 25, wherein said decomposition step comprises photolysis.
